(19) United States
(12) Patent Application Publication
(10) Pub. No.: US 2024/0371441 A1
(43) Pub. Date: Nov. 7, 2024

(54) CONFIGURATION BIT CIRCUIT FOR PROGRAMMABLE LOGIC DEVICE WITH PHASE CHANGE RANDOM ACCESS MEMORY AND PROGRAM AND OPERATION METHOD THEREOF

(71) Applicant: Revol-Ver Inc., Yongin-si (KR)

(72) Inventor: Sung Lae CHO, Gwacheon-si (KR)

(21) Appl. No.: 18/652,970

(22) Filed: May 2, 2024

(30) Foreign Application Priority Data
May 3, 2023 (KR) 10-2023-0057716

(51) Int. Cl. G11C 13/00

(52) U.S. Cl. CPC G11C 13/0069; G11C 13/0038

(57) ABSTRACT

In order to provide a configuration bit circuit utilizing a phase change memory, the configuration bit circuit for a programmable logic device may include a first phase change memory element and a second phase change memory element connected in series between a first power source and a second power source, a first selection element connected to the first phase change memory element and second phase change memory element in a first direction, and a CMOS inverter connected to the first phase change memory element and second phase change memory element in a second direction and disposed between a third power source and a fourth power source.

### CROSS-REFERENCE TO RELATED APPLICATIONS

This application claims the priority of Korean Patent Application No. 10-2023-0057716 filed on May 3, 2023, in the Korean Intellectual Property Office, the disclosure of which is incorporated herein by reference.

### BACKGROUND OF THE INVENTION

### 1. Field of the Invention

The present invention relates to a configuration bit circuit for a programmable logic device including a phase change memory, and to a configuration bit circuit for preventing phase change of the phase change memory during operation and an operation method thereof.

### 2. Description of the Related Art

A field programmable gate array (FPGA) is a device whose function is not fixed during manufacture but has a specific function through programming by a user, and is a type of programmable logic device (PLD). Due to the variable characteristics the FPGA, the FPGA has recently been linked with the 4th industrial revolution and its uses are expanding very widely to communication equipment, automobiles, industrial use, and artificial intelligence.

As illustrated in FIG. 1, such an FPGA generally includes a logic block (LB), a connection block (CB) and a switch block (SB), each of which includes a configuration bit that may be programmed by the user to allow the entire FPGA to have a circuit according to a user's intention.

FIG. 1 illustrates that configuration bits M1 and M2 are used in the respective blocks (the logic block, the switch block, the connection block, etc.) on the FPGA circuit. For example, the configuration bit M1 is a memory element that configures a routing resource and is placed inside, outside, and on the periphery of the logic block, and the configuration bit M2 becomes a memory element that allows a lookup table to be configured in various ways.

In FPGAs up to now, 6-T SRAM has been mainly used in the configuration bit circuit, and accordingly, an excessive area is required, and due to the nature thereof as a volatile memory, a separate memory device should be placed outside the FPGA and stored information should be loaded each time it is driven. Therefore, it takes time to drive and a lot of energy is inevitably consumed, and in particular, there is a high possibility that a security problem will occur. In addition, there is a possibility of damage due to radiation when used in airplanes, etc.

In order to overcome these shortcomings of SRAM, there is an attempt to construct the configuration bit using a phase change memory, and a technology for constructing the configuration bit circuit through a 1T-2P structure connecting two phase change memories and one selection element was proposed at P. E. Gaillardon et al., “Phase-Change-Memory-Based Storage Elements for Configurable Logic”, 2010 International Conference on Field-Programmable Technology.

The structure, operation, and programming method of the configuration bit circuit having such a 1T-2P structure are illustrated in FIGS. 2 and 3. FIG. 2 is a diagram illustrating the structure and programming method of a configuration bits 100 composed of 1T-2P.

FIG. 2(a) illustrates creating a low resistance state SET by flowing a current into a phase change memory 110, and FIG. 2(b) illustrates creating the low resistance state SET by flowing a current into a phase change memory 120. In this case, since the phase change memories 110 and 120 have a complementary relationship, when one is in the low resistance state SET, the other is in a high resistance state RST. When programming one phase change memory, the other phase change memory is made to be a floating state to prevent current from flowing.

Meanwhile, FIG. 3 is a diagram illustrating an operation mode of the configuration bit 100 composed of 1T-2P.

In FIG. 3(a), the phase change memory 110 is in a low resistance state SET, and thus a voltage of 1.2 V applied from a power source VOP1 is applied to a gate electrode of a transistor 210 of an FPGA logic 200 circuit through the phase change memory 110. The phase change memory 120 is in the high resistance state RST, and thus the current passing through the phase change memory 110 from the power source 111 does not flow or flows very weakly. Due to this voltage divider effect, the voltage from the power source VOP1 passes through the phase change memory 120 and becomes an output voltage (VOUT=1.2 V). Therefore, the configuration bit 100 of FIG. 3(a) outputs the voltage (VOUT=1.2 V).

In contrast, FIG. 3(b) illustrates a case where the phase change memory 110 is in the high resistance state RST. In this case, the voltage of 1.2 V applied from the power source VOP1 does not pass through the phase change memory 110, and 0 V of a ground power source VOP2 is applied to the gate electrode of the transistor 210 of the FPGA logic 200 circuit.

However, as an operating voltage of a general logic circuit applied to the configuration bits 100, a voltage higher than a threshold voltage of the phase change memory may be used. FIGS. 3(a) and (b) illustrate an example in which 1.2 V is applied, and this applied voltage may be higher than the threshold voltage of a general phase change memory. If a voltage greater than the threshold voltage is applied to the phase change memory, there is a concern that not only the phase change memory that is intended to be in the low resistance state but also the phase change memory in the high resistance state will be turned on and changed to the low resistance state.

FIG. 4 illustrates an I-V curve of the phase change memory. In the memory in the high resistance state RST, the I-V curve has a threshold voltage Vth, and thus when a voltage greater than the threshold voltage is applied, it turns on and a large current flows instantaneously, and accordingly, the memory in the high resistance state may be phase-changed to the low resistance state. As illustrated in FIG. 4, when a voltage V1 lower than the threshold voltage Vth is applied, only a small current I1 flows and there is no possibility of a phase change occurring, but when a voltage V2 higher than the threshold voltage Vth is applied, a large current I2 flows and accordingly, the possibility of the phase change occurring increases.

However, an operating voltage level of a logic circuit, which is commonly used, is higher than a threshold voltage of a normal phase change memory when considering the threshold voltage, and thus there is a high possibility of turning it on. In this case, in an operation mode of the 1T-2P configuration bit 100 in FIG. 3(a), the second phase change memory 120, which is in the high resistance state RST, may be phase-changed to the low resistance state SET by the applied voltage. In this case, both memories may be in the low resistance state SET, which may cause a problem in which the signal cannot be accurately transmitted from the configuration bit 100 to the FPGA logic 200. In addition, in FIG. 3(b), when the voltage from the power source VOP1 is equal to or greater than the threshold voltage of the phase change memory 110, the phase change memory may be phase-changed from the high resistance state to the low resistance state, and accordingly, stored information may change and an incorrect signal may be transmitted to the FPGA logic 200.

Thus, the configuration bit circuit having the 1T-2P structure has a problem that programmed information may be changed during operation due to the characteristics of the phase change memory.

### SUMMARY OF THE INVENTION

An aspect of the present invention is to provide a configuration bit circuit for a programmable logic device including a phase change memory.

Another aspect of the present invention is to provide a method of programming a configuration bit circuit for a programmable logic device including a phase change memory, and a method of operating the same.

According to an embodiment of the invention, there is provided a configuration bit circuit for a programmable logic device including a first phase change memory element and a second phase change memory element connected in series between a first power source and a second power source, a first selection element connected to the first phase change memory element and second phase change memory element in a first direction, and a CMOS inverter connected to the first phase change memory element and second phase change memory element in a second direction and disposed between a third power source and a fourth power source.

In addition, in the configuration bit circuit for the programmable logic device according to the embodiment of the invention, the first selection element may be a transistor.

In addition, in the configuration bit circuit for the programmable logic device according to the embodiment of the invention, the first selection element may be a transmission gate.

In addition, in the configuration bit circuit for the programmable logic device according to the embodiment of the invention, the first selection element may be a two-terminal switching element.

In addition, in the configuration bit circuit for the programmable logic device according to the embodiment of the invention, the two-terminal switching element may be any one of an ovonic threshold switch, a transition metal oxide switch, a MIEC switch, a complementary resistance switch, and doped amorphous silicon.

In addition, in the configuration bit circuit for the programmable logic device according to the embodiment of the invention, a phase change layer of the first phase change memory element and second phase change memory element may include Ge, Sb, and Te, and may be Ge <50 at %, Sb<40 at %, and Te≥50 at % at an atomic ratio.

According to another embodiment of the invention, there is provided a method of operating a configuration bit circuit for a programmable logic device, in which a voltage applied by the first power source or second power source is lower than a threshold voltage when the first phase change memory and second phase change memory are in a high resistance state.

In addition, in the method of operating the configuration bit circuit for the programmable logic device according to the embodiment of the present invention, the voltage applied by the first power source or second power source may be lower than a threshold voltage when the first phase change memory and second phase change memory are in a high resistance state.

In addition, in the method of operating the configuration bit circuit for the programmable logic device according to the embodiment of the present invention, the voltage applied by the first power source or second power source may be lower than the threshold voltage when the first phase change memory and second phase change memory are in the high resistance state and may be higher than a threshold voltage of an NMOS transistor included in the CMOS inverter.

In addition, in the method of operating the configuration bit circuit for the programmable logic device according to the embodiment of the present invention, the voltage applied by the first power source or second power source may be 0.5 times or less than a voltage applied to the third power source or the fourth power source.

According to still another embodiment of the invention, there is provided a method of programming a configuration bit circuit for a programmable logic including a phase change memory, in particular, the configuration bit circuit including a transmission gate as a selection element for programming, the method including, when a voltage applied to the transmission gate from one of the first power source and the second power source through one of the first phase change memory and the second phase change memory is referred to as a first polarity voltage and a voltage applied from the transmission gate through one of the first phase change memory and the second phase change memory to one of the first power source and the second power source is referred to as a second polarity voltage, programming one of the first phase change memory and the second phase change memory to be in a first resistance state by the first polarity voltage, and programming one of the first phase change memory and the second phase change memory to be in a second resistance state by the second polarity voltage, in which one of the first phase change memory and the second phase change memory is in the first resistance state and the other is in the second resistance state, one of the first resistance state and the second resistance state refers to a low resistance state because the phase change memory is in a crystalline phase, and the other refers to a high resistance state because the phase change memory is in an amorphous phase.

According to still yet another embodiment of the invention, there is provided a programmable logic device including a configuration bit circuit for the programmable logic device.

According to the present invention, the programmable logic device including an FPGA device to which the configuration bit circuit using the phase change memory is applied reduces manufacturing costs, has a small area, has excellent security, and is resistant to radiation.

### BRIEF DESCRIPTION OF THE DRAWINGS

FIG. 1 is a diagram illustrating the application of a configuration bit in an FPGA device;

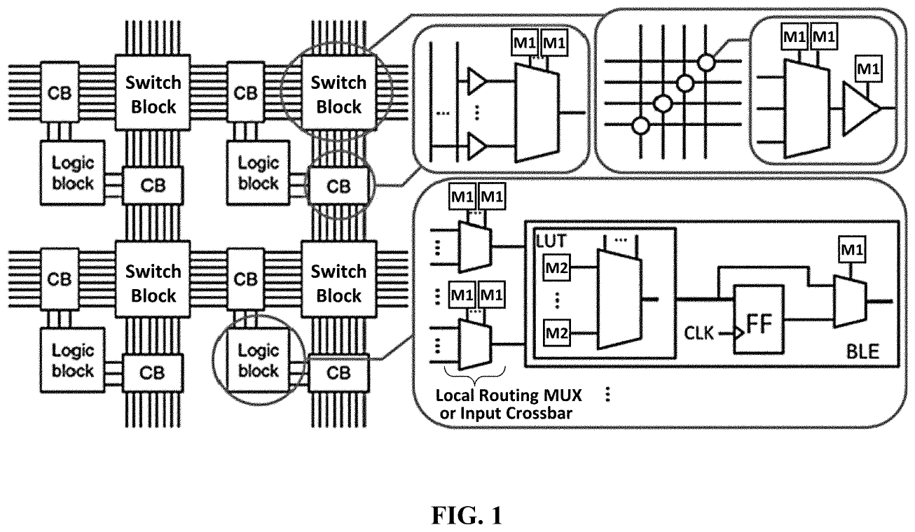

FIG. 2 is a diagram illustrating a program mode in a conventional bit circuit using a PCM;

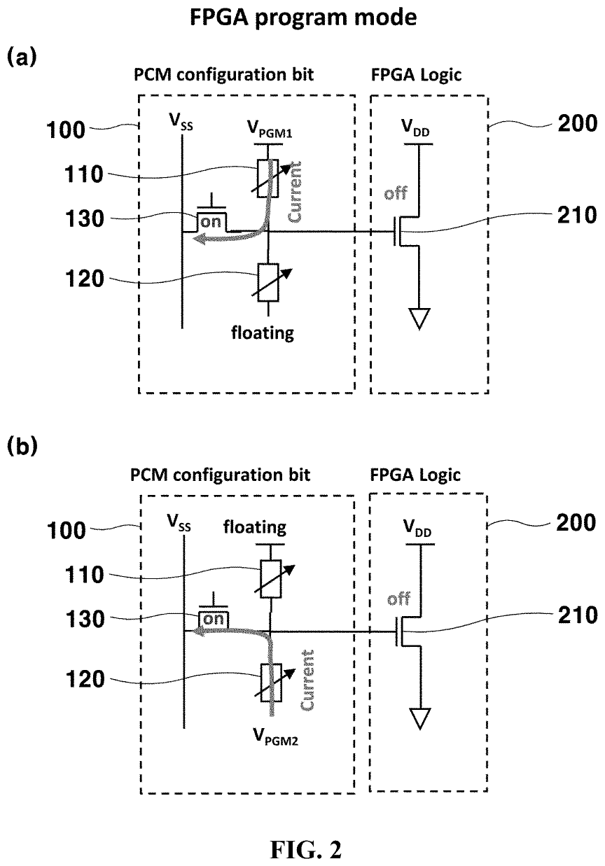

FIG. 3 is a diagram illustrating an operation mode in the configuration bit circuit using the conventional PCM;

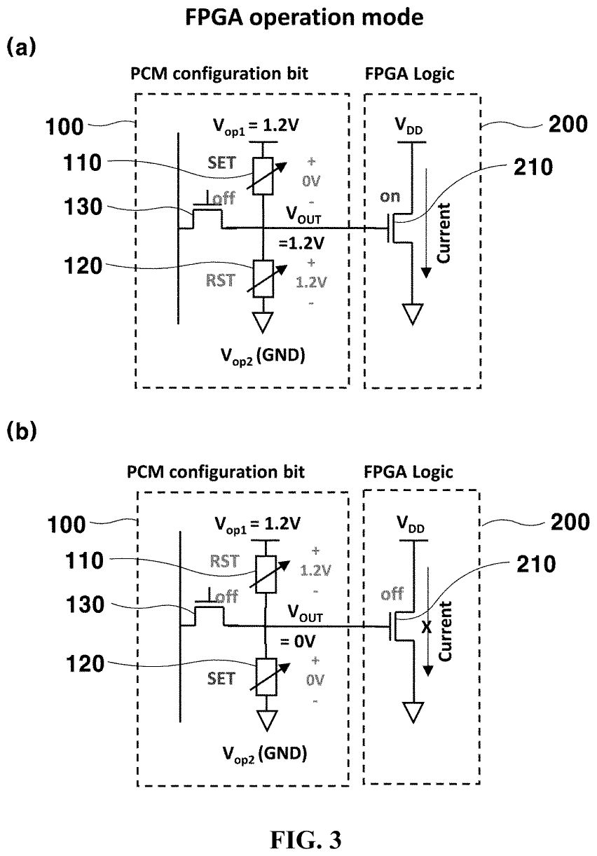

FIG. 4 is a graph illustrating a general I-V curve of a phase change memory;

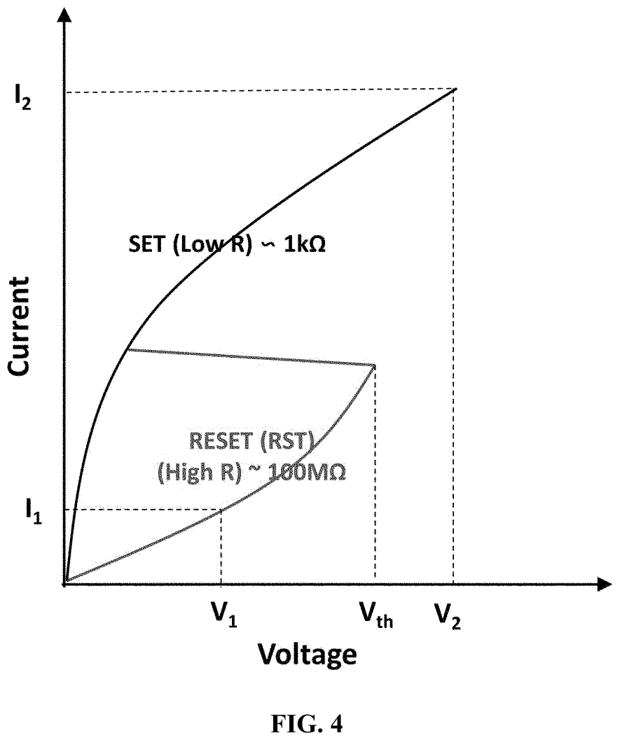

FIG. 5 is a circuit diagram illustrating a configuration bit circuit according to an embodiment of the present invention;

FIG. 6 is a diagram illustrating an operation of a configuration bit circuit according to an embodiment of the present invention;

FIG. 7 is a diagram illustrating an operation of a configuration bit circuit according to an embodiment of the present invention;

FIG. 8 is a diagram illustrating an operation of a configuration bit circuit according to an embodiment of the present invention;

FIG. 9 is a diagram illustrating an operation of a configuration bit circuit according to an embodiment of the present invention;

FIG. 10 is a graph illustrating a change in resistance of a phase change memory according to voltage application in both directions;

FIG. 11 is a diagram illustrating a method of programming a configuration bit circuit according to an embodiment; and

FIG. 12 is a diagram illustrating a method of programming a configuration bit circuit according to an embodiment.

### DETAILED DESCRIPTION OF THE EXEMPLARY EMBODIMENTS

Hereinafter, embodiments of the present invention will be described in detail with reference to the accompanying drawings so that those of ordinary skill in the art to which the present application belongs can easily implement them. However, the present application may be implemented in various different forms and is not limited to the embodiments described herein.

In addition, in order to clearly describe the present application in the drawings, parts unrelated to the description have been omitted, and similar reference numerals have been assigned to similar parts throughout the specification.

Throughout the specification of the present application, when a part is said to be “connected” to another part, this includes not only cases where it is “directly connected,” but also cases where it is “electrically connected” with another element in between.

Throughout the specification of the present application, when a member is said to be located “on”, “on an upper part”, “at the top”, “below”, “at a lower part”, or “at the bottom” of another member, this includes not only cases where the member is in contact with another member, but also cases where another member exists between two members.

Throughout the specification of the present application, when a part is said to “include” a certain constituent element, this means that it can further include other constituent elements rather than excluding other constituent elements, unless specifically stated to the contrary.

As used in this specification, the terms “approximately”, “substantially”, etc. are used to mean at or close to that numerical value when manufacturing and material tolerances unique to the meaning mentioned are given, and are used to prevent unscrupulous infringers from unfairly using the disclosed contents in which accurate or absolute numerical values are mentioned in order to aid the understanding of the present invention. In addition, throughout the specification of the present application, “a step of doing ˜” or “a step of ˜” does not mean “a step for ˜”.

Throughout the specification of the present application, the term “combination thereof” means a mixture or combination of one or more selected from a group consisting of the constituent elements described in the expression of the Makushi format, and means including one or more selected from the group consisting of the constituent elements.

Throughout the specification of the present application, the description of “A and/or B” means “A or B, or A and B”.

A configuration bit circuit for a programmable logic device according to the present invention may include a first phase change memory element and a second phase change memory element connected to each other in series between a first power source and a second power source, a first selection element connected to the first phase change memory element and second phase change memory element in a first direction, and a CMOS inverter connected to the first phase change memory element and second phase change memory element in a second direction and disposed between a third power source and a fourth power source.

The configuration bit circuit according to the present invention capable of storing a logic by including a phase change memory element and capable of operating accordingly is installed in a programmable logic device (PLD) such as an FPGA to control the connection of the entire circuit according to stored information.

The included first selection element allows a voltage to be applied from the first power source or second power source when programming the phase change memory that can store a logic state to change a phase of the first phase change memory or the second phase change memory, thereby allowing a resistance state to be changed.

The first selection element may be a transistor or a two-tunnel switch. In general, although a transistor is used to control a flow of current in a circuit, it is possible to increase a degree of integration and reduce power consumption by applying a two-terminal switching element as a selection element for selecting a phase change memory cell. The two-terminal switching element may be a device such as an ovonic threshold switch, a transition metal oxide switch, an MIEC switch, a complementary resistance switch, doped amorphous silicon, etc.

In addition, the first selection element may be a transmission gate. The transmission gate specifically allows a current to flow in both directions, and the conductivity of the phase change memory element is changed by this bidirectional current, and accordingly, the threshold voltage of the phase change memory is allowed to be set high.

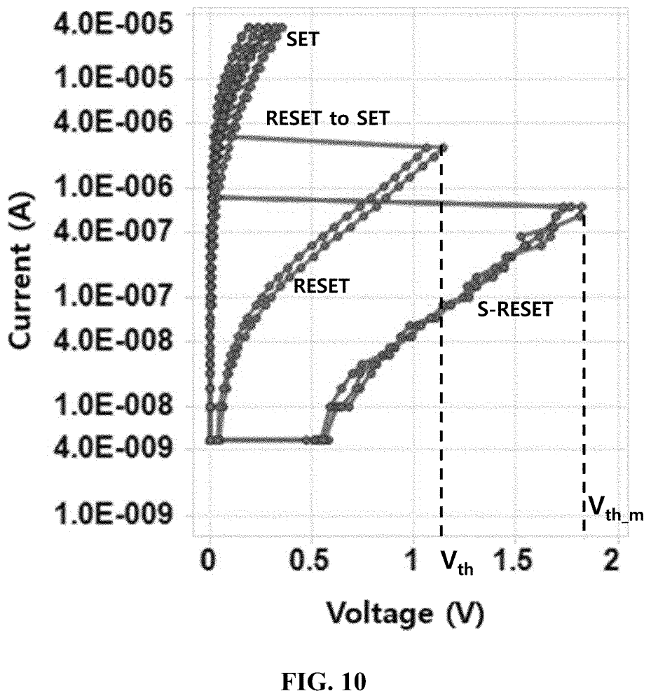

The change in conductivity due to the current flowing in both directions of the phase change memory will be described using FIG. 10. FIG. 10 is a graph illustrating an I-V curve of the phase change memory. In FIG. 10, the phase change memory in a first high resistance state RESET, which is generally a high resistance state, is turned on at a voltage higher than a first threshold voltage Vth and is converted to a low resistance state (RESET to SET), which is a crystallized state.

Meanwhile, if a voltage of opposite polarity (negative voltage in FIG. 10) of a certain magnitude or more is applied to the phase change memory in the low resistance state, it is converted to a second high resistance state S-RESET (SET to S-RESET), which is a higher resistance state than the first high resistance state RESET, which is a normal high resistance state. In order to convert the phase change memory converted to the second high resistance state S-RESET back to the low resistance state, a voltage equal to or greater than a second threshold voltage Vth_m should be applied. The reason that the high resistance level can be divided even in the high resistance state is because, even in the amorphous state of high resistance, differences in resistance may appear depending on the composition distribution within the amorphous state.

In this way, when the transmission gate is applied as the selection element, the conductivity of the phase change memory element can be adjusted by bidirectional current, and accordingly, the threshold voltage can be raised high when it is in a high resistance state. As described above, when the configuration bit circuit operates, since the voltage applied by the first power source or second power source should be lower than the threshold voltage of the phase change memory, there is an advantage in that a selection range of an application voltage is expanded.

The configuration bit circuit according to the present invention has a configuration in which the CMOS inverter is added to the selection element and two phase change memories in which the resistance states can be programmed. The resistance states of the two phase change memories are programmed to be complementary, so that the voltage applied during operation and the voltage according to the resistance state of the phase change memory are applied to the CMOS inverter.

This structure with the addition of the inverter makes it possible to prevent the phase change memory included in the configuration bits from unintentionally changing phase by differentiating the voltage applied to the phase change memory and the voltage applied to the inverter during operation.

By making the threshold voltage when the phase change memory element is in a high resistance state higher than the operating voltage of a general circuit, it is possible to prevent unwanted phase changes in the phase change memory element even during operation at high voltage. The threshold voltage may be increased by controlling the thickness and/or composition of the phase change layer of the phase change memory. This makes it possible to prevent unintended phase changes of the phase change memory during operation by making the threshold voltage in the high resistance state of phase change memory higher than the operating voltage of a general circuit.

To this end, in the present invention, the phase change layer of the phase change memory element includes Ge, Sb, and Te, and the atomic ratio thereof may be Ge<50 at %, Sb<40 at %, and Te≥50 at %. In such a composition, the threshold voltage can be maintained high.

In describing the method of operating the configuration bit circuit according to the present invention for preventing an unintended phase change of the phase change memory during operation, the voltage applied by the first power source or second power source may be lower than the threshold voltage when the first change memory and second phase change memory are in the high resistance state. Even if a voltage of a third power source applied to the CMOS inverter is the voltage used in a general logic circuit (e.g., 1.2 V, 3.3 V), the voltage applied to the phase change memory by the first power source or second power source is maintained to be lower than the threshold voltage of the phase change memory, thereby capable of preventing unwanted phase change in the change memory.

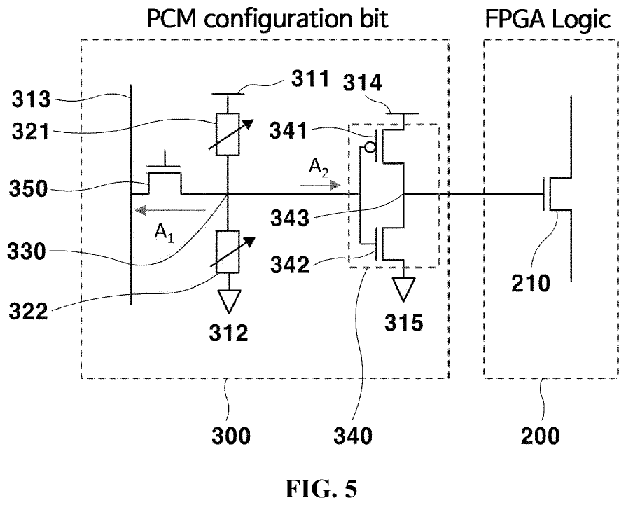

FIG. 5 is a circuit diagram illustrating a configuration bit circuit according to an embodiment of the present invention. A transistor 210 disposed in the FPGA logic circuit 200 operates according to the voltage output from a configuration bit circuit 300.

In FIG. 5, a first phase change memory 321 and a second phase change memory 322 are disposed between a first power source 310 and a second power source 320. A first selection element 350, which is a transistor, is disposed and connected in a first direction A1 from a first node 330 located between the first phase change memory 321 and the first phase change memory 350. A first node 330. The first selection element 350, which is a transistor, is again connected to a fifth power source 313. A CMOS inverter 340 is disposed and connected between a third power source 314 and a fourth power source 315 in a second direction A2, which is the opposite direction thereof, from the first node 330. A PMOS transistor 341 and an NMOS transistor 342 are disposed in the CMOS inverter 340. The PMOS transistor 341 and the NMOS transistor 342 are connected in series between the third power source 314 and the fourth power source 315, and a second node 343 is disposed between them. Finally, an output terminal comes out from the second node 343 of the CMOS inverter 340, and this output terminal is connected to a gate electrode of the transistor 210 of the FPGA logic circuit 200.

As described above, the operation of the configuration bit circuit having a structure obtained by combining this 1T-2P structure and the CMOS inverter can prevent an unwanted phase change in the phase change memory by making the voltage applied to the phase change memory and the voltage applied to the CMOS inverter different.

To this end, the method of operating the configuration bit circuit according to the present invention is such that the voltage applied by the first power source or second power source is lower than the threshold voltage when the first phase change memory and second phase change memory are in the high resistance state.

More specifically, the voltage applied by the first power source or second power source is 1.0 V or less, and more preferably 0.6 V or less. In general, the PCM with Ge—Sb—Te composition is known to have a threshold voltage of around 1.0 V. Therefore, the voltage of the first power source or second power source that applies a voltage to the phase change memory is preferably lower than this level. When considering the threshold voltage distribution of the memory, it is preferably 1.0 V or less, and more preferably 0.6 V or less. In addition, the voltage applied by the first power source or second power source may be 0.5 times or less than the voltage applied to the third power source or fourth power source.

Meanwhile, the voltage applied to the first second power source or second power source is lower than the threshold voltage when the first phase change memory and second phase change memory are in the high resistance state, and at the same time, is higher than the threshold voltage of the NMOS transistor included in the CMOS inverter. The voltage applied through the phase change memory element is applied to the gate electrode of the PMOS transistor and NMOS transistor included in the CMOS inverter. In order to operate these transistors, the voltage applied to these gate electrodes should be greater than the threshold voltage of the NMOS transistor.

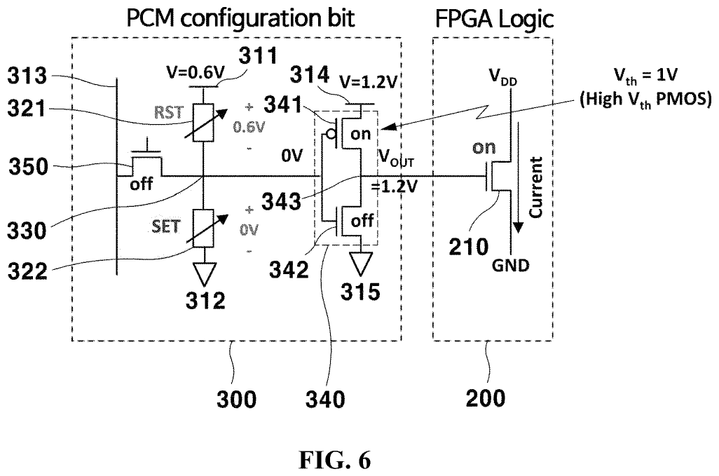

One embodiment of the method of operating the configuration bit circuit 300 according to the present invention will be described with reference to FIG. 6. FIG. 6 illustrates the operation in the same configuration bit circuit 300 as in FIG. 5. FIG. 6 illustrates the configuration bit circuit 300 in which the first phase change memory element 321 is in the high resistance state RST and the second phase change memory element 322 is in the low resistance state SET. During operation, the transistor 350, which is the first selection element, is in an off state and does not flow a current. During operation, 0.6 V is applied from the first power source 311 and the second power source 312 becomes a ground power source. In addition, the voltage applied to the CMOS inverter 340 from the third power source 314 was set to 1.2 V, which is a circuit operating voltage, and the fourth power source 315 on the opposite side was set to be a ground power source. Since the first phase change memory element 321 is in the high resistance state RST, a current does not pass through the first phase change memory element 321 at the voltage of 0.6 V applied by the first power source 311. In particular, since the first phase change memory element cannot be turned on at such a low voltage of 0.6 V, an unwanted phase changes can be prevented.

Meanwhile, since a current cannot flow through the first phase change memory element 321 by the voltage applied by the first power source 311, 0 V, which is a ground voltage, is applied to the CMOS inverter 340 through the second phase change memory element 322. The PMOS transistor 341 and the NMOS transistor 342 are disposed in the CMOS inverter 340. The voltage is applied from the first node 330 to each of the gate electrodes of the PMOS transistor 341 and the NMOS transistor 342. Since the voltage applied to the gate electrode is 0 V, the PMOS transistor 341 is brought into an on state and the NMOS transistor 342 is brought into an off state. Since a voltage of 1.2 V, which is the operating voltage, is applied from the third power source, the voltage of 1.2 V is applied to the gate electrode of the transistor 210 of the FPGA logic circuit 200 through the PMOS transistor 341 and the second node 343. Through this application of the voltage, a current can be allowed to flow in the FPGA logic circuit 200.

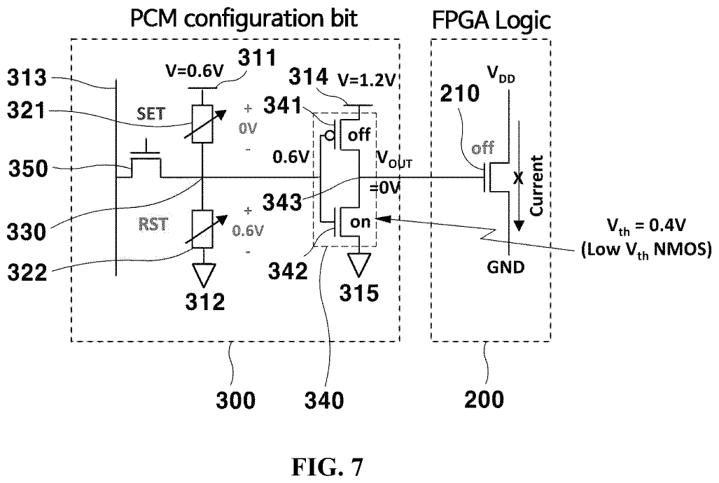

With reference to FIG. 7, an embodiment in which the resistance states of the first phase change memory element 321 and second phase change memory element 322 are opposite to those of FIG. 6 will be described. In this case, the voltage applied from the first power source 311 is applied to the CMOS inverter 340 through the first memory element 321 and the first node 330. The voltage applied to the CMOS inverter 340 becomes 0.6 V by the first power source 311. Meanwhile, since 0.6 V, which is the voltage applied from the first power source 311, is lower than the threshold voltage of the phase change memory element, there is no risk that the second phase change memory element 322, which is in the high resistance state, will phase change to a low resistance state.

The voltage of 0.6 V applied to the CMOS inverter 340 is applied to the gate electrode of each transistor of the inverter to bring the PMOS transistor 341 into an off state and bring the NMOS transistor 342 an on state. In particular, since the threshold voltage of the NMOS transistor 342 is 0.4 V, the NMOS transistor 342 may be brought into the on state even with the voltage of 0.6 V flowing through the first phase change memory 321.

As in FIG. 6, the voltage of 1.2 V, which is the operating voltage, is applied from the third power source, and since the PMOS transistor 341 is in the off state, 0 V of the ground power source, which is the fourth power source, is applied to the gate electrode of the transistor 210 of the FPGA logic circuit 200 through the second node 343.

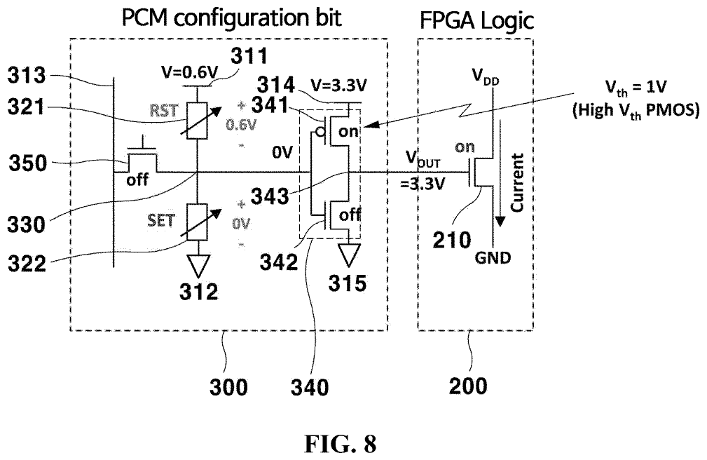

With reference to FIG. 8, another embodiment in which 3.3 V is applied to the third power source in the bit circuit 300 having the same structure as that of FIG. 6 will be described. FIG. 8 illustrates the case where the first phase change memory 321 is in the high resistance state and the second phase change memory 322 is in the low resistance state as in FIG. 6, and 0.6 V was applied from the first power source 311 and the second power source 312 was set to be a ground power source during operation, as in FIG. 6. And the voltage applied to the CMOS inverter 340 from the third power source 314 was set to 3.3 V.

In this case, the voltage output through the phase change memories 321 and 322 is 0 V, and thus the PMOS transistor 341 is brought into the on state in the CMOS inverter 340, and through this, the voltage output from the CMOS inverter 340 becomes 3.3 V. This voltage is applied to the gate electrode of the transistor 210 of the FPGA logic circuit 200 to allow the current to flow in the FPGA logic circuit 200.

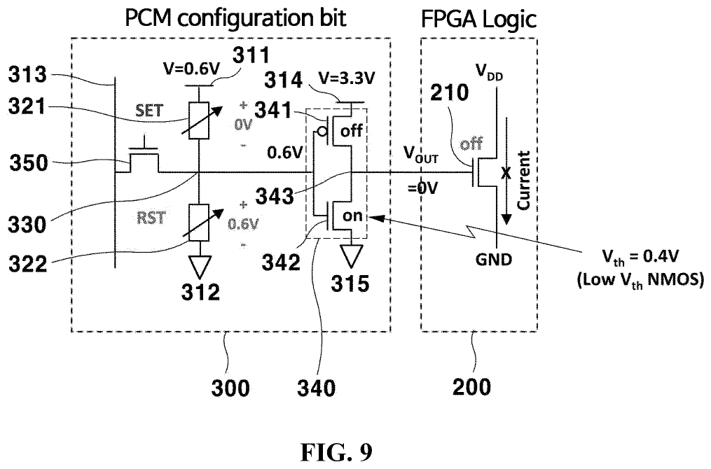

FIG. 9 is a diagram illustrating an embodiment in which, when the first phase change memory 321 is in the low resistance state SET and the second phase change memory 322 is in the high resistance state RST in the same configuration bit circuit 300, 0.6 V is applied by the first power source and an operating voltage of 3.3 V is applied to the third power source 314.

In this case as well, the voltage of 0.6 V applied from the first power source 311 is applied to the CMOS inverter 340 through the first phase change memory 321 in the low resistance state. Accordingly, the PMOS transistor 341 of the CMOS inverter 340 is brought into the off state and the NMOS transistor 342 is brought into the on state, so that the voltage of the fourth power source 315, which is a ground power source, is output.

In this way, in the component bit circuit according to the present invention, the voltage applied to derive information programmed in the phase change memory is made lower than the threshold voltage of the phase change memory, independently of the general operating voltage of the circuit, thereby capable of preventing an unwanted change in electrical conductivity of the phase change memory during operation of the component bit circuit.

Meanwhile, when the first selection element is the transmission gate, the threshold voltage of the phase change memory may be set high in the programming step.

To describe this in more detail, it may be a method of programming configuration bit circuit, in which, when a voltage applied to a transmission gate from one of the first power source or the second power source through one of the first phase change memory or the second phase change memory is referred to as a first polarity voltage and a voltage applied from the transmission gate through one of the first phase change memory or the second phase change memory to one of the first power source or the second power source is referred to as a second polarity voltage, one of the first phase change memory or the second phase change memory becomes a first resistance state by the first polarity voltage and one of the first phase change memory or the second phase change memory becomes a second resistance state by the second polarity voltage, one of the first phase change memory and the second phase change memory is in the first resistance state and the other is in the second resistance state, one of the first resistance state and the second resistance state may refer to a low resistance state because the phase change memory is in a crystalline phase, and the other may refer to a high resistance state because the phase change memory is in an amorphous phase.

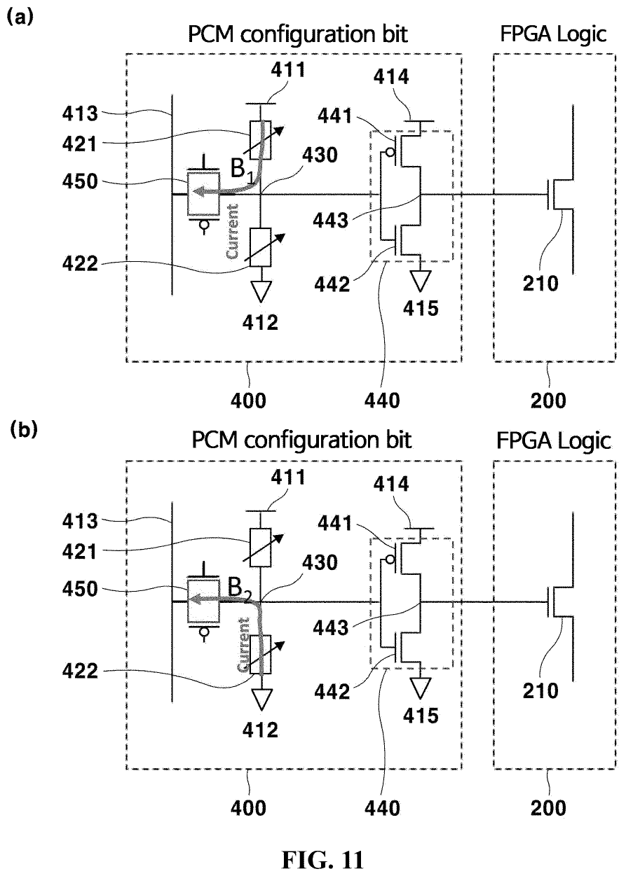

To describe this programming method in more detail with reference to FIG. 11, FIG. 11 illustrates that, when a voltage applied from the first power source 411 disposed adjacent to the first phase change memory 421 or the second power source 412 disposed adjacent to the second phase change memory 422 in the directions B1 and B2 of the transmission gate 450 is referred to as a first polarity voltage, a first phase change memory 421 or a second phase change memory 422 is programmed through the first polarity voltage.

The first polarity voltage is a voltage of the same polarity as when the actual configuration bit circuit operates, and through the first polarity voltage, the first phase change memory 421 or the second phase change memory 422 may be programmed to be in the low resistance state SET. In this case, when a voltage is applied to the first phase change memory 421, the second phase change memory 422 becomes to be in a floating state, and conversely, when a voltage is applied to the second phase change memory 422, the first phase change memory 421 becomes to be in the floating state.

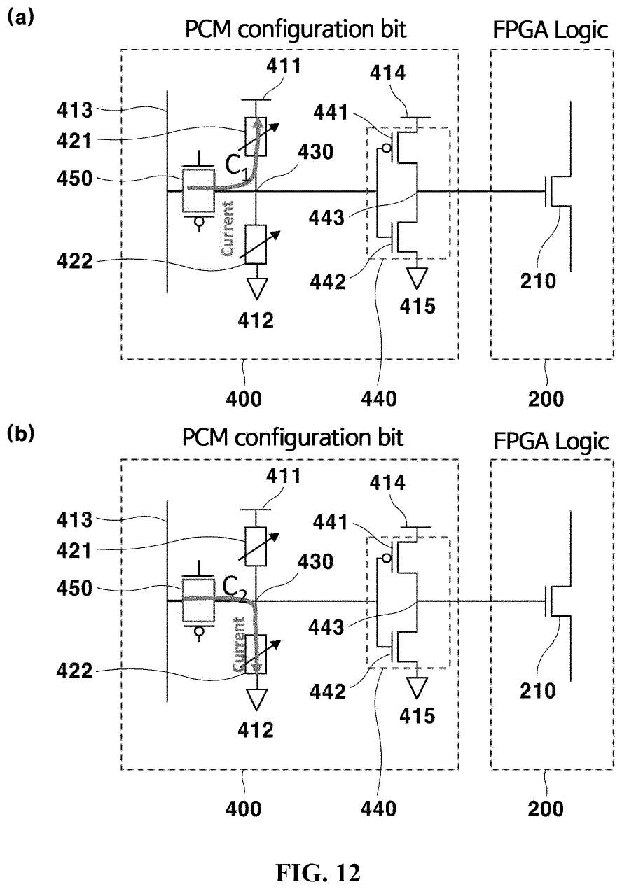

Meanwhile, FIG. 12 illustrates that the first phase change memory 421 or the second phase change memory 422 is programmed through the second polarity voltage. The second polarity voltage refers to a voltage applied from the transmission gate in the direction C1 or C2 of the first power source or second power source, as opposed to the first polarity voltage. When a magnitude of the second polar voltage becomes equal to or greater than a predetermined magnitude, the phase change memory has the high resistance state S-RESET among the amorphous states. As in FIG. 11, when a voltage is applied to one of the phase change memories, the other maintains the floating so as to prevent the phase change from occurring at the same time. In the phase change memory having such a high resistance state S-RESET, the threshold voltage thereof becomes higher (Vth_m in FIG. 10).

In this way, the resistance state of the first phase change memory 421 and second phase change memory 422 may be programmed by changing the resistance state to the low resistance state SET or the high resistance state S-RESET through the voltage applied in both directions, and accordingly, the threshold voltage can be maintained high. Phase change memories are programmed so that when one of them is in the low resistance state SET, the other is in the high resistance state S-RESET.

The programmable logic device including the configuration bit circuit capable of being provided according to the present invention can reduce time when starting up, have a small area, have excellent security, and are resistant to radiation, compared to the conventional programmable logic elements that include the SRAM-based configuration bit circuit.

What is claimed is:

1. A configuration bit circuit for a programmable logic device comprising:
a first phase change memory element and a second phase change memory element connected in series between a first power source and a second power source;
a first selection element connected to the first phase change memory element and second phase change memory element in a first direction; and
a CMOS inverter connected to the first phase change memory element and second phase change memory element in a second direction and disposed between a third power source and a fourth power source.

2. The configuration bit circuit according to claim 1,
wherein the first selection element is a transistor.

3. The configuration bit circuit according to claim 1,
wherein the first selection element is a transmission gate.

4. The configuration bit circuit according to claim 1,
wherein the first selection element is a two-terminal switching element.

5. The configuration bit circuit according to claim 4,
wherein the two-terminal switching element is any one of an ovonic threshold switch, a transition metal oxide switch, a MIEC switch, a complementary resistance switch, and doped amorphous silicon.

6. The configuration bit circuit according to claim 1,
wherein a phase change layer of the first phase change memory element and second phase change memory element includes Ge, Sb, and Te, and may be Ge<50 at %, Sb<40 at %, and Te≥50 at % at an atomic ratio.

7. A method of operating the configuration bit circuit according to claim 1,
wherein a voltage applied by the first power source or second power source is lower than a threshold voltage when the first phase change memory element and second phase change memory element are in a high resistance state.

8. The method according to claim 7,
wherein the voltage applied by the first power source or second power source is higher than a threshold voltage of an NMOS transistor included in CMOS inverter.

9. The method according to claim 7,
wherein the voltage applied by the first power source or second power source may be 0.5 times or less than a voltage applied to the third power source or the fourth power source.

10. A method of programming the configuration bit circuit for the programmable logic element including the phase change memory according to claim 3, the method comprising:
when a voltage applied to the transmission gate from one of the first power source and the second power source through one of the first phase change memory element and the second phase change memory element is referred to as a first polarity voltage and a voltage applied from the transmission gate through one of the first phase change memory element and the second phase change memory element to one of the first power source and the second power source is referred to as a second polarity voltage,
programming one of the first phase change memory element and the second phase change memory element to be in a first resistance state by the first polarity voltage; and
programming one of the first phase change memory element and the second phase change memory element to be in a second resistance state by the second polarity voltage,
wherein one of the first phase change memory element and the second phase change memory element is in the first resistance state and the other is in the second resistance state,
one of the first resistance state and the second resistance state refers to a low resistance state because the phase change memory element is in a crystalline phase, and the other refers to a high resistance state because the phase change memory element is in an amorphous phase.

11. A programmable logic element including the configuration bit circuit according to claim 1.
